(19) United States
(12) Patent Application Publication
(10) Pub. No.: US 2009/0189168 A1
(43) Pub. Date: Jul. 30, 2009

(54) White Light Emitting Device

(76) Inventor: Kai-Shon Tsai, Lujhou City (TW)

Correspondence Address: LIN & ASSOCIATES INTELLECTUAL PROPERTY, INC., P.O. BOX 2339, SARATOGA, CA, 95070-0339, US

(21) Appl. No.: 12/021,309

(22) Filed: Jan. 29, 2008

(51) Int. Cl. H01L 33/00

(52) U.S. Cl. 257/98; 257/E33.061

(57) ABSTRACT

A white light emitting device is provided, which includes a light emitting element that emits a first light having a wavelength between 300 nm and 410 nm; and a fluorescent layer positioned over the light emitting element. The fluorescent layer includes a fluorescent whitening agent capable of absorbing at least a portion of the first light, and subsequently emitting a second light having a wavelength between 420 nm and 510 nm; and a photoluminescent material capable of absorbing at least a portion of the first light and at least a portion of the second light, and subsequently emitting a third light having a wavelength longer than wavelengths of the first light and the second light.

### BACKGROUND OF THE INVENTION

1. Field of the Invention

The present invention generally relates to a light emitting device, and in particular to a light emitting device which can produce white light with enhanced luminous efficiency and brightness using UV light source.

2. The Prior Arts

White light-emitting diode (LED) is rapidly evolving for use in the special and general illumination applications. A main method for producing white light emitting device is to utilize a blue LED chip and phosphors which have the characteristic of wavelength-conversion. Most white light emitting device today are made from blue InGaN LED chips coated with a precise quantity of a phosphor material that can convert a portion of the blue light emitted from the LED chip into yellow light. The resulting blend of blue and yellow light is perceived as white. The phosphor material most commonly used to make a white light emitting device is YAG:Ce because it absorbs light made by blue LEDs and converts it to a fairly broad (from greenish to reddish but mostly yellow) emission. YAG is a crystalline material (garnet) made from yttrium, aluminum and oxygen doped with cerium (which does the light conversion).

The blue light source is usually used in the conventional white light emitting device which includes a blue light source used together with YAG:Ce phosphor. However, when a white light emitting device work, the substantial amounts of heat can be generated by the blue light source, and thereby the voltage applied to the conventional white light emitting device cannot be high. Consequently, the brightness of the white light produced by the conventional light emitting device has a limit to how high it can go. In the future, the applicability of the white light emitting devices is expected to extend to a general illumination field. Due to the low power of single LED, the luminance of single LED is not high. Therefore, there is a need for improving luminous efficiency and brightness of the white light emitting devices.

### SUMMARY OF THE INVENTION

Accordingly, the objective of the present invention is to provide a white light emitting device which has high luminous efficiency and brightness by using UV light source in order to overcome the problems set forth above.

To achieve the foregoing objective, the present invention provides a white light emitting device, comprising a light emitting element made of nitride-based compound semiconductor, and a fluorescent layer positioned over the light emitting element, wherein the light emitting element can emit a first light having a wavelength between 300 nm and 410 nm. Moreover, the fluorescent layer comprises a fluorescent whitening agent capable of absorbing at least a portion of the first light and subsequently emitting a second light having a wavelength between 420 nm and 510 nm; and a photoluminescent material capable of absorbing at least a portion of the first light and at least a portion of the second light and subsequently emitting a third light having a wavelength longer than wavelengths of the first light and the second light. The photoluminescent material has a Ce-activated garnet structure represented by general formula A₃B₅O₁₂, where the first component A contains at least one element selected from the group consisting of Y, La, Gd and Sm, and the second component B contains at least one element selected from the group consisting of Al, Ga and In.

The present invention further provides a white light emitting device, comprising a light emitting element made of nitride-based compound semiconductor, and an encapsulant layer surrounding the light emitting element, wherein the light emitting element can emit a first light having a wavelength between 300 nm and 410 nm. The encapsulant layer comprises a fluorescent whitening agent capable of absorbing at least a portion of the first light and subsequently emitting a second light having a wavelength between 420 nm and 510 nm; and a photoluminescent material capable of absorbing at least a portion of the first light and at least a portion of the second light and subsequently emitting a third light having a wavelength longer than wavelengths of the first light and the second light. The encapsulant layer transmits the first light, second light, and third light as composite output light in a direction away from the light emitting element, and the composite output light is a white light. The photoluminescent material has a Ce-activated garnet structure represented by general formula A₃B₅O₁₂, where the first component A contains at least one element selected from the group consisting of Y, La, Gd, and Sm, and the second component B contains at least one element selected from the group consisting of Al, Ga and In.

The white light emitting device of the present invention can advantageously exhibit increased luminous efficiency and emission brightness as compared with those of the conventional white light emitting devices including a blue light source used together with YAG phosphor.

The foregoing and other objectives, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a graph showing intensity (μW) versus wavelength (300 to 400 nm) of irradiation according to one embodiment of the present invention, in which the dashed-line curve represents a fluorescent whitening agent-YAG-resin mixture, and the solid-line curve represents a YAG-resin mixture;

FIG. 2 is a graph showing luminous efficiency (LM/W) versus wavelength (300 to 400 nm) of irradiation according to one embodiment of the present invention, in which the dashed-line curve represents a fluorescent whitening agent-YAG-resin mixture, and the solid-line curve represents a YAG-resin mixture;

FIG. 3 is a graph showing intensity (μW) versus wavelength (350 to 395 nm) of irradiation according to the embodiment of the present invention as shown in FIG. 1, in which the dashed-line curve represents a fluorescent whitening agent-YAG-resin mixture, and the solid-line curve represents a YAG-resin mixture;

FIG. 4 is a graph showing luminous efficiency (LM/W) versus wavelength (350 to 395 nm) of emission according to the embodiment of the present invention as shown in FIG. 2, in which the dashed-line curve represents a fluorescent whitening agent-YAG-resin mixture, and the solid-line curve represents a YAG-resin mixture;

FIG. 5 is a graph showing brightness (LM) versus wavelength (350 to 395 nm) of emission according to the embodiment of the present invention as shown in FIG. 3, in which the dashed-line curve represents a fluorescent whitening agent-YAG-resin mixture, and the solid-line curve represents a YAG-resin mixture; and

FIGS. 6A-6J are CIE chromaticity diagrams illustrating the trails of the change in chromaticity of OYAG and YAG at the irradiation wavelength of 350 nm, 355 nm, 360 nm, 365 nm, 370 nm, 375 nm, 380 nm, 385 nm, 390 nm, and 395 nm, respectively, in which OYAG represents a fluorescent whitening agent-YAG-resin mixture denoted by a symbol of large green square, and YAG represents a YAG-resin mixture denoted by a symbol of a small red square.

### DETAILED DESCRIPTION OF THE PREFERRED EMBODIMENT

In accordance with one embodiment of the present invention, the white light emitting device comprises a light emitting element emitting a first light having a wavelength between 300 nm and 410 nm; and a fluorescent layer positioned over the light emitting element. The fluorescent layer comprises a fluorescent whitening agent capable of absorbing at least a portion of the first light and subsequently emitting a second light having a wavelength between 420 nm and 510 nm; and a photoluminescent material capable of absorbing at least a portion of the first light and at least a portion of the second light and subsequently emitting a third light having a wavelength between 530 nm and 590 nm. Preferably, the light emitting element is a light emitting diode having an InGaN multi-quantum-well structure. Examples of the fluorescent whitening agent include, but are not limited to, 4,4′-bis(2-methoxystyryl)-1,1′-biphenyl, 1,4-bis(2-benzoxazoly)benzene, 1,4-bis(2-benzoxazoly)naphthalene, and pyrene. Furthermore, the photoluminescent material has a Ce-activated garnet structure represented by general formula A₃B₅O₁₂, where the first component A contains at least one element selected from the group consisting of Y, La, Gd and Sm, and the second component B contains at least one element selected from the group consisting of Al, Ga and In. Preferably, the photoluminescent material has a Ce-activated garnet structure represented by general formula (Y_{1-p-q-r}GdₚCe_{q}Smᵣ)₃(Al₁₋ₛGaₛ)₅O₁₂, where 0≦p≦0.8, 0.003≦q≦0.2, 0.0003≦r≦0.08, and 0≦s≦1.

The white light emitting device of the present invention further comprises an encapsulant layer surrounding the light emitting element and the fluorescent layer, wherein the encapsulant layer is optically coupled to the fluorescent layer to transmit the first light, second light, and third light as composite white light in a direction away from the light emitting element. Preferably, the encapsulant layer is made of a transparent resin.

In accordance with the other embodiment of the present invention, the white light emitting device comprises a light emitting element emitting a first light having a wavelength between 300 nm and 410 nm, and an encapsulant layer surrounding the light emitting element. Preferably, the light emitting element is a light emitting diode having an InGaN multi-quantum-well structure. The encapsulant layer comprises a fluorescent whitening agent capable of absorbing at least a portion of the first light and subsequently emitting a second light having a wavelength between 420 nm and 510 nm; and a photoluminescent material capable of absorbing at least a portion of the first light and at least a portion of the second light and subsequently emitting a third light having a wavelength between 530 nm and 590 nm. Preferably, the encapsulant layer is substantially made of a transparent resin. In the encapsulant layer, the transparent resin is present in an amount of from 80.00 to 94.99% by weight of total weight of the encapsulant layer, the fluorescent whitening agent is present in an amount of from 0.01 to 5% by weight of total weight of the encapsulant layer, and the photoluminescent material is present in an amount of from 5.00 to 15.00% by weight of total weight of the encapsulant layer. Examples of the fluorescent whitening agent include, but are not limited to, 4,4′-bis(2-methoxystyryl)-1,1′-biphenyl, 1,4-bis(2-benzoxazoly)benzene, 1,4-bis(2-benzoxazoly)naphthalene, and pyrene. The encapsulant layer can transmit the first light, second light, and third light as composite white light in a direction away from the light emitting element. The photoluminescent material has a Ce-activated garnet structure represented by general formula A₃B₅O₁₂, where the first component A contains at least one element selected from the group consisting of Y, La, Gd, and Sm, and the second component B contains at least one element selected from the group consisting of Al, Ga and In. Preferably, the photoluminescent material has a Ce-activated garnet structure represented by general formula (Y_{1-p-q-r}GdₚCe_{q}Smᵣ)₃(Al₁₋ₛGaₛ)₅O₁₂, where 0≦p≦0.8, 0.003≦q≦0.2, 0.0003≦r≦0.08, and 0≦s≦1.

### Example

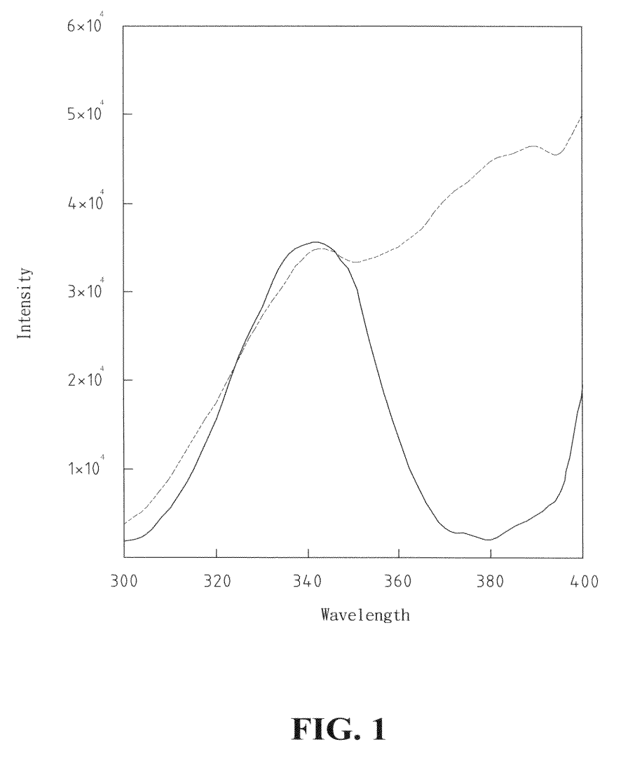

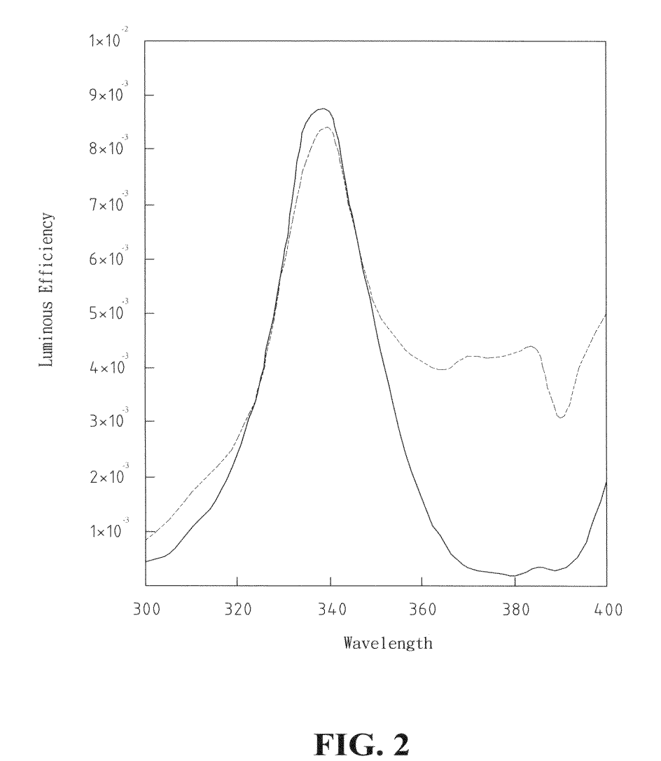

The fluorescent whitening agent-YAG-resin mixture is prepared by mechanically mixing 90.0% by weight of silicone resin with 0.01% by weight of 4,4′-bis(2-methoxystyryl)-1,1′-biphenyl (using as fluorescent whitening agent) and 9.99% by weight of cerium-doped YAG. Subsequently, the photonic spectrum is obtained by irradiating the fluorescent whitening agent-YAG-resin mixture with an irradiation light in a wavelength region of 300 to 400 nm and recording the intensity as a function of wavelength, and the obtained photonic spectrum is as shown in FIG. 1 in which the dashed-line curve represents the fluorescent whitening agent-YAG-resin mixture. Furthermore, The YAG-resin mixture is prepared by mechanically mixing 90.0% by weight of silicone resin with 10% by weight of cerium-doped YAG. Subsequently, the photonic spectrum is obtained by irradiating the YAG-resin mixture with an irradiation light in a wavelength region of 300 to 400 nm and recording the intensity as a function of wavelength, and the obtained photonic spectrum is also as shown in FIG. 1 in which the solid-line curve represents a YAG-resin mixture. Also, the spectral luminous efficiency as a function of wavelength is measured in LM/W for the fluorescent whitening agent-YAG-resin mixture and the YAG-resin mixture, respectively, as shown in FIG. 2 in which the dashed-line curve represents a fluorescent whitening agent-YAG-resin mixture, and the solid-line curve represents a YAG-resin mixture.

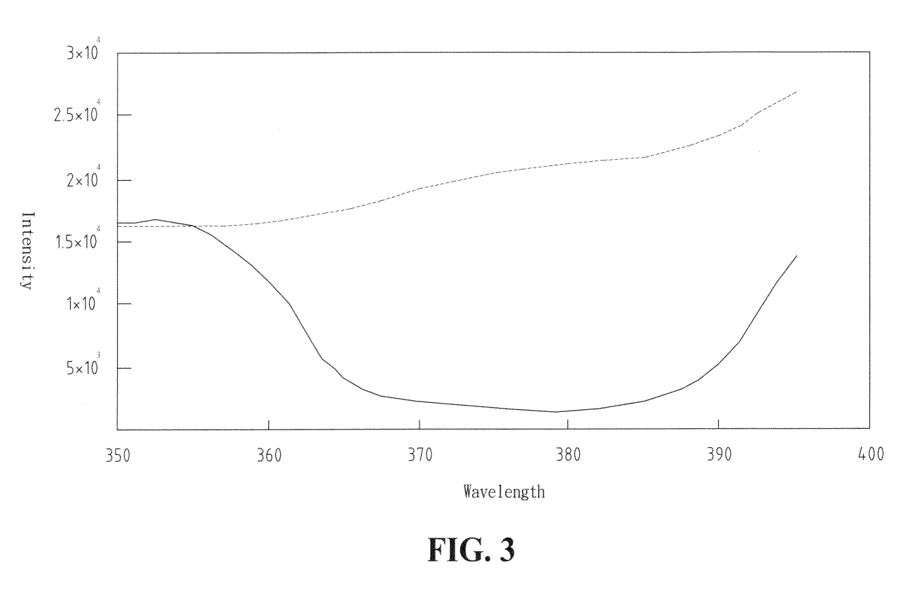

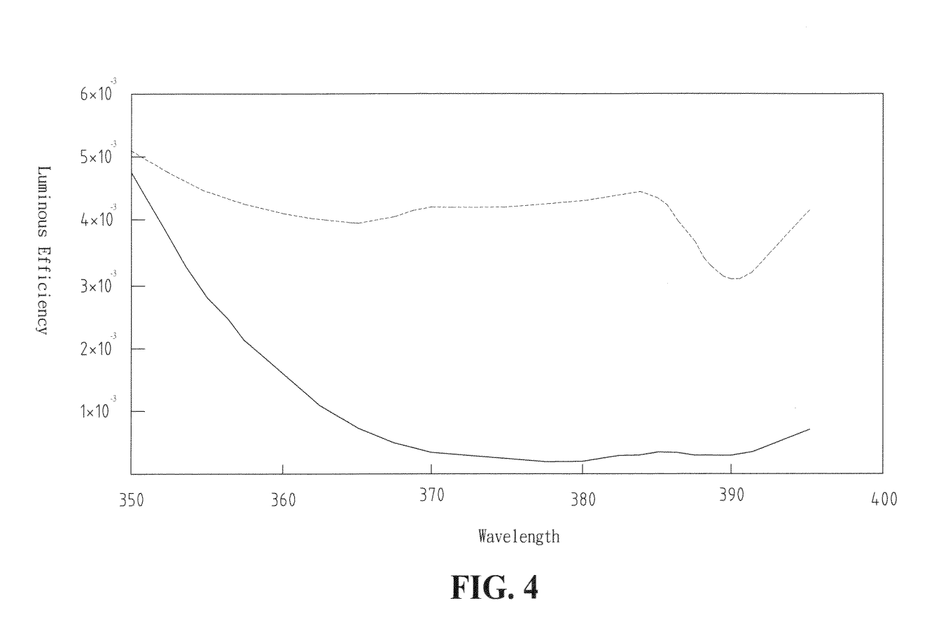

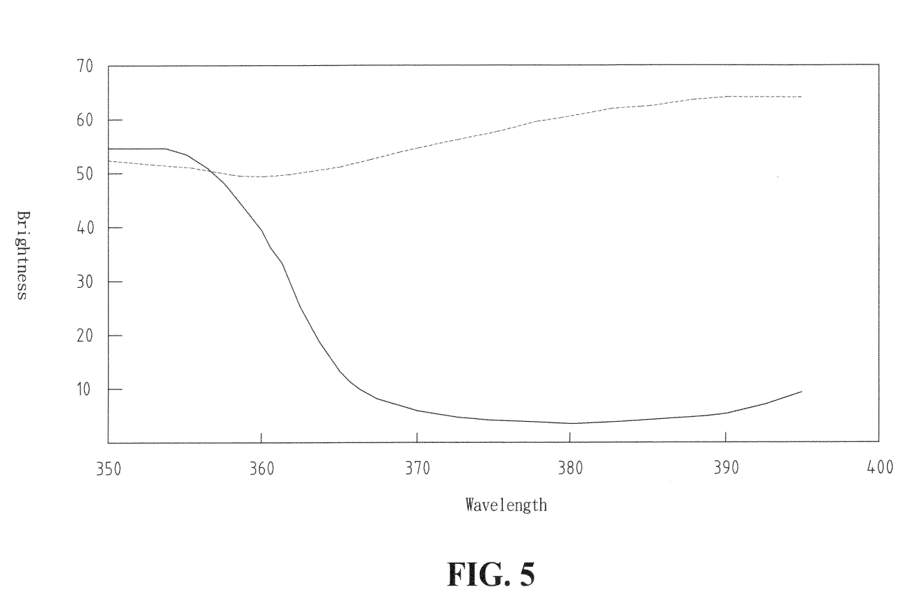

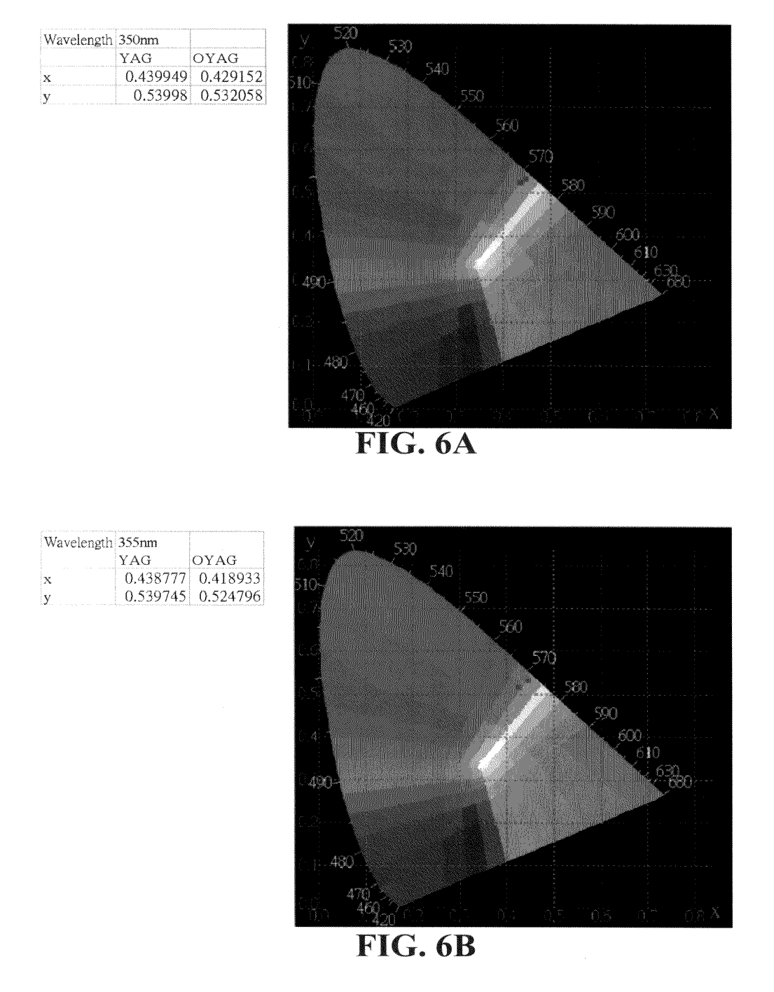

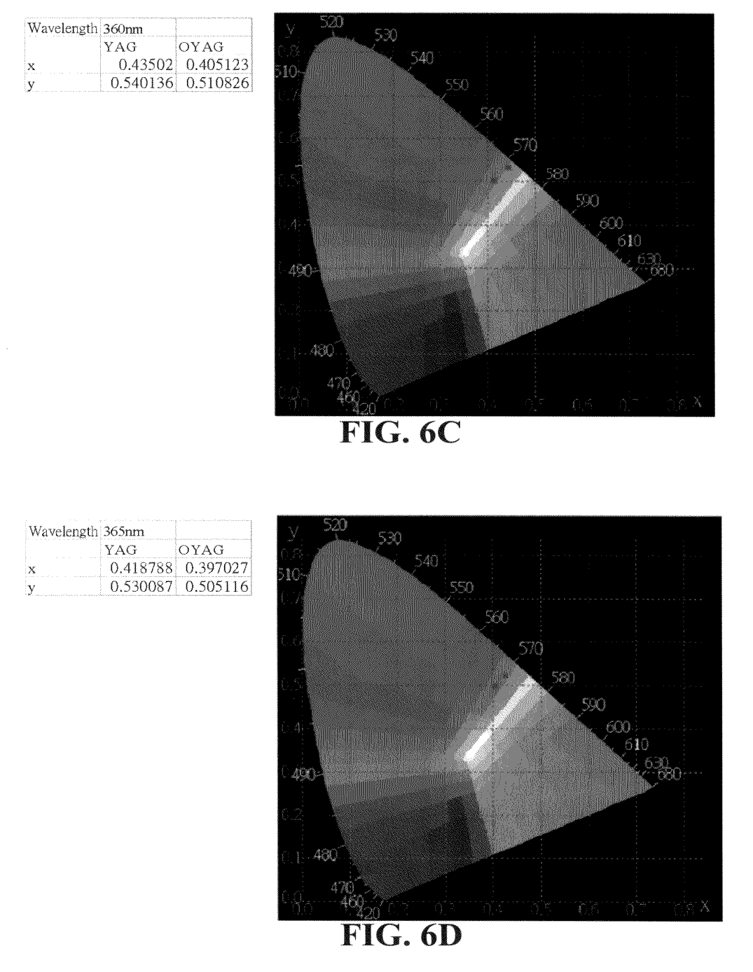

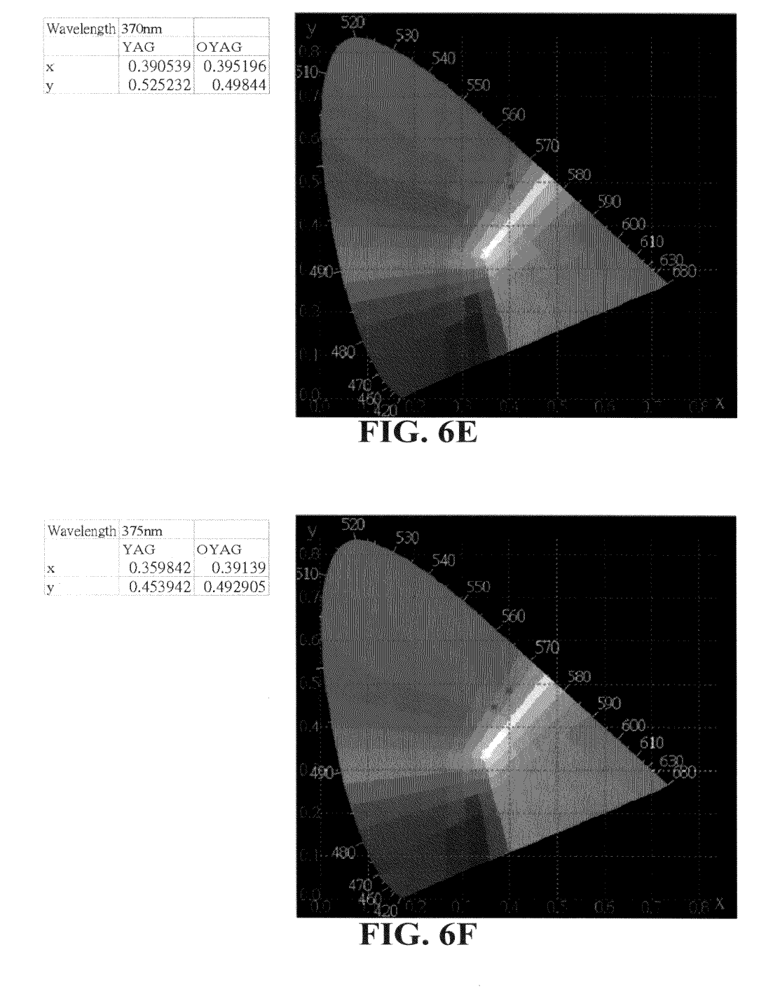

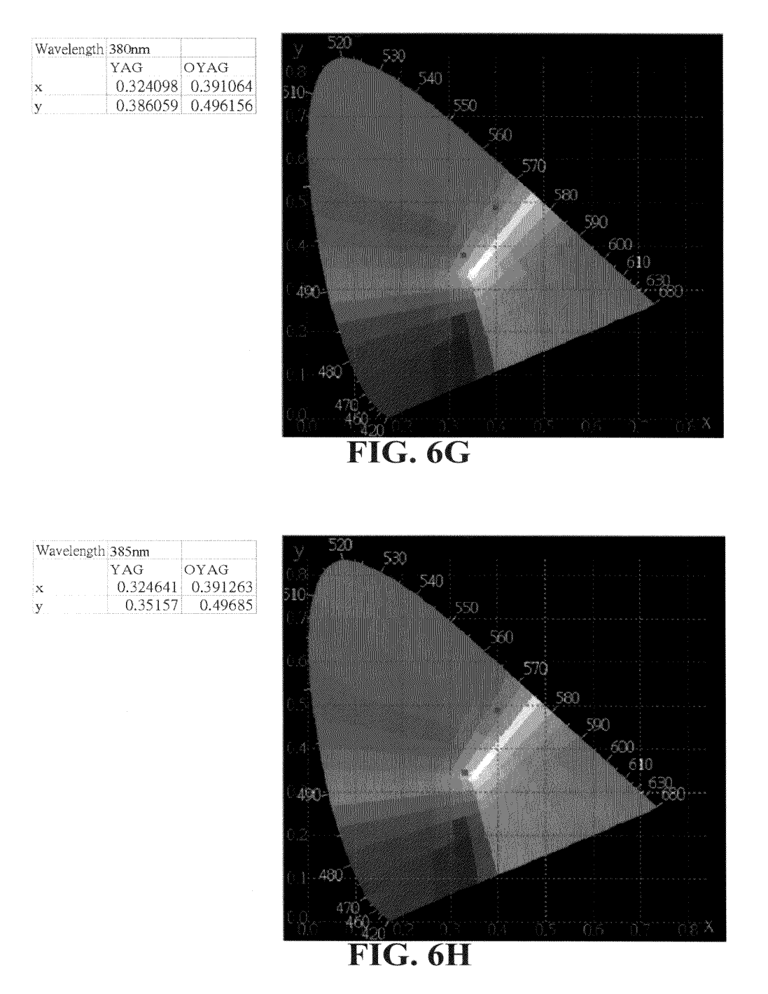

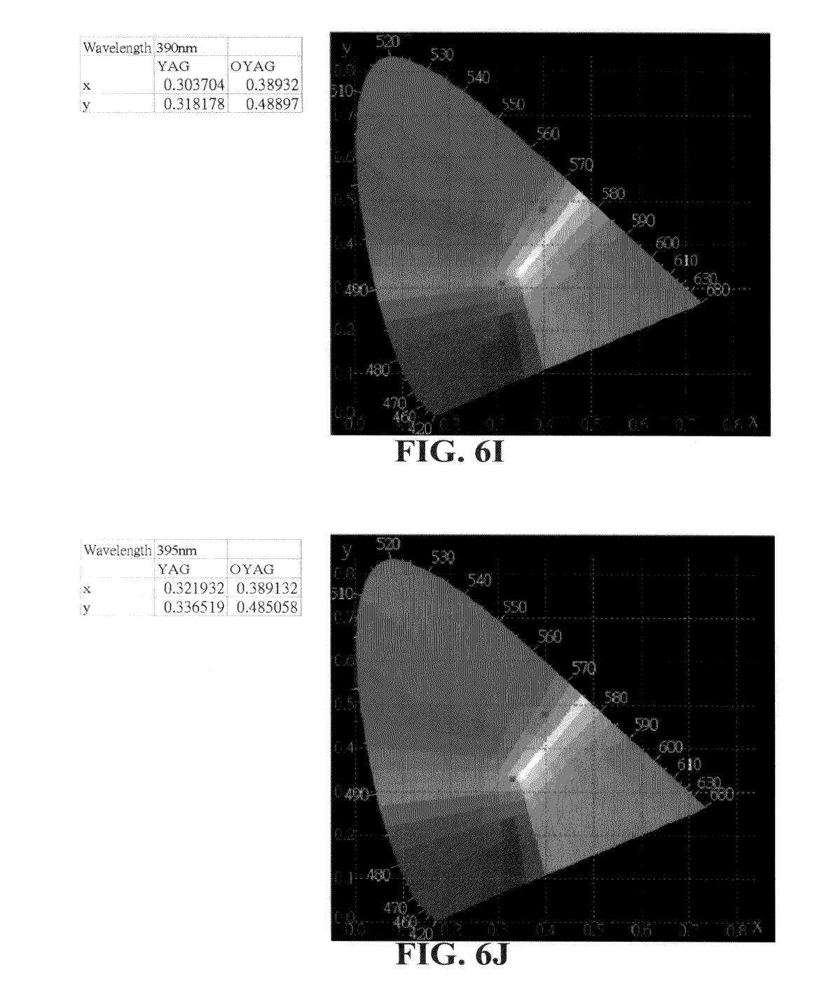

Furthermore, from FIGS. 6A-6J, we can see that the light emitting device of the present invention can emit white light in an irradiation light wavelength region of about 375 to about 395 nm. In order to obtain detailed spectral profile in a wavelength region of 350 to 395 nm, another photonic spectrum is obtained by irradiating the above-mentioned fluorescent whitening agent-YAG-resin mixture with a light in a wavelength region of 350 to 395 nm and recording the intensity as a function of wavelength, and the obtained photonic spectrum is as shown in FIG. 3 in which the dashed-line curve represents the fluorescent whitening agent-YAG-resin mixture. Moreover, the other photonic spectrum is obtained by irradiating the above-mentioned YAG-resin mixture with a light in a wavelength region of 350 to 395 nm and recording the intensity as a function of wavelength, and the obtained photonic spectrum is also as shown in FIG. 3 in which the solid-line curve represents a YAG-resin mixture. Also, the spectral luminous efficiency (in LM/W) as a function of wavelength is measured for the fluorescent whitening agent-YAG-resin mixture and the YAG-resin mixture, respectively, as shown in FIG. 4 in which the dashed-line curve represents a fluorescent whitening agent-YAG-resin mixture, and the solid-line curve represents a YAG-resin mixture. Moreover, the brightness (in LM) as a function of wavelength is measured for the fluorescent whitening agent-YAG-resin mixture and the YAG-resin mixture, respectively, as shown in FIG. 5 in which the dashed-line curve represents a fluorescent whitening agent-YAG-resin mixture, and the solid-line curve represents a YAG-resin mixture.

From FIGS. 1, 3, and 5 and FIGS. 6A-6J, it can see that the white light emitting device of the present invention using a fluorescent whitening agent and YAG:Ce as fluorescent materials can produce much higher intensity of white light when the irradiation light having a wavelength between about 375 nm to about 400 nm as compared with the conventional white light emitting device only using YAG:Ce as fluorescent material.

It is to be understood that the fluorescent whitening agent discussed above is exemplary, but not restrictive. Moreover, the fluorescent whitening agents used in the present invention can be any organic fluorescent whitening agents as long as they are capable of absorbing part of the light having a wavelength of 250 nm to 470 nm emitted by the light source and subsequently emitting the light having a wavelength of 380 nm to 660 nm.

Accordingly, the white light emitting device of the present invention can advantageously produce white light when the irradiation light used is in the UV wavelength range, but the conventional white light emitting device cannot produce white light when the irradiation light used is in the UV wavelength range, please see FIGS. 6A-6J. Therefore, in the white light emitting device of the present invention, a much higher efficiency UV light can be used as light source instead of the blue light source for producing white light.

It will be apparent to those skilled in the art that various modifications and variations can be made in the present invention without departing from the spirit or scope of the present invention. Thus, it is intended that the present invention cover the modifications and the variations of this invention provided they come within the scope of the appended claims and their equivalents.

What is claimed is:

1. A white light emitting device, comprising:
a light emitting element made of nitride-based compound semiconductor, the light emitting element emitting a first light having a wavelength between 300 nm and 410 nm; and
a fluorescent layer positioned over the light emitting element, the fluorescent layer comprising:
a fluorescent whitening agent capable of absorbing at least a portion of the first light, and subsequently emitting a second light having a wavelength between 420 nm and 510 nm;
a photoluminescent material capable of absorbing at least a portion of the first light and at least a portion of the second light, and subsequently emitting a third light having a wavelength longer than wavelengths of the first light and the second light, the photoluminescent material having a Ce-activated garnet structure represented by general formula A₃B₅O₁₂, where the first component A contains at least one element selected from the group consisting of Y, La, Gd and Sm, and the second component B contains at least one element selected from the group consisting of Al, Ga and In.

2. The white light emitting device as claimed in claim 1, further comprising an encapsulant layer surrounding the light emitting element and the fluorescent layer, the encapsulant layer being optically coupled to the fluorescent layer to transmit the first light, second light, and third light as composite output light in a direction away from the light emitting element, the composite output light being a white light.

3. The white light emitting device as claimed in claim 1, wherein the photoluminescent material has a Ce-activated garnet structure represented by general formula (Y_{1-p-q-r}GdₚCe_{q}Smᵣ)₃(Al₁₋ₛGaₛ)₅O₁₂, where 0≦p≦0.8, 0.003≦q≦0.2, 0.0003≦r≦0.08, and 0≦s≦1.

4. The white light emitting device as claimed in claim 1, wherein the third light has a wavelength between 530 nm and 590 nm.

5. The white light emitting device as claimed in claim 1, wherein the fluorescent brightening agent is selected from the group consisting of 4,4′-bis(2-methoxystyryl)-1,1′-biphenyl, 1,4-bis(2-benzoxazoly)benzene, 1,4-bis(2-benzoxazoly)naphthalene, and pyrene.

6. The white light emitting device as claimed in claim 2, wherein the encapsulant layer is made of a transparent resin.

7. The white light emitting device as claimed in claim 1, wherein the light-emitting element is a light emitting diode having an InGaN multi-quantum-well structure.

8. A white light emitting device, comprising:
a light emitting element made of nitride-based compound semiconductor, the light emitting element emitting a first light having a wavelength between 300 nm and 410 nm; and
an encapsulant layer surrounding the light emitting element, the encapsulant layer comprising:
a fluorescent whitening agent capable of absorbing at least a portion of the first light, and subsequently emitting a second light having a wavelength between 420 nm and 510 nm;
a photoluminescent material capable of absorbing at least a portion of the first light and at least a portion of the second light, and subsequently emitting a third light having a wavelength longer than wavelengths of the first light and the second light, the photoluminescent material having a Ce-activated garnet structure represented by general formula A₃B₅O₁₂, where the first component A contains at least one element selected from the group consisting of Y, La, Gd and Sm, and the second component B contains at least one element selected from the group consisting of Al, Ga and In.
wherein the encapsulant layer transmits the first light, second light, and third light as composite output light in a direction away from the light emitting element, the composite output light being a white light.

9. The white light emitting device as claimed in claim 8, wherein the photoluminescent material has a Ce-activated garnet structure represented by general formula (Y_{1-p-q-r}GdₚCe_{q}Smᵣ)₃(Al₁₋ₛGaₛ)₅O₁₂, where 0≦p≦0.8, 0.003≦q≦0.2, 0.0003≦r≦0.08, and 0≦s≦1.

10. The white light emitting device as claimed in claim 8, wherein the third light has a wavelength between 530 nm and 590 nm.

11. The white light emitting device as claimed in claim 8, wherein the fluorescent brightening agent is selected from the group consisting of 4,4′-bis(2-methoxystyryl)-1,1′-biphenyl, 1,4-bis(2-benzoxazoly)benzene, 1,4-bis(2-benzoxazoly)naphthalene, and pyrene.

12. The white light emitting device as claimed in claim 8, wherein the encapsulant layer is substantially made of a transparent resin.

13. The white light emitting device as claimed in claim 12, wherein the transparent resin is present in an amount of from 80.00 to 94.99% by weight of total weight of the encapsulant layer.

14. The white light emitting device as claimed in claim 12, wherein the fluorescent whitening agent is present in an amount of from 0.01 to 5% by weight of total weight of the encapsulant layer.

15. The white light emitting device as claimed in claim 12, wherein the photoluminescent material is present in an amount of from 5.00 to 15.00% by weight of total weight of the encapsulant layer.

16. The white light emitting device as claimed in claim 8, wherein the light emitting element is a light-emitting diode having an InGaN multi-quantum-well structure.
